(19) United States
(12) Patent Application Publication
(10) Pub. No.: US 2011/0045182 A1
(43) Pub. Date: Feb. 24, 2011

(54) SUBSTRATE PROCESSING APPARATUS, TRAP DEVICE, CONTROL METHOD FOR SUBSTRATE PROCESSING APPARATUS, AND CONTROL METHOD FOR TRAP DEVICE

(75) Inventor: Koji Fukumori, Yamanashi (JP)

Correspondence Address: IPUSA, P.L.L.C, 1054 31ST STREET, N.W., Suite 400, Washington, DC, 20007, US

(73) Assignee: Tokyo Electron Limited, Tokyo (JP)

(21) Appl. No.: 12/990,672

(22) PCT Filed: Mar. 1, 2010
(86) PCT No.: PCT/JP2010/053271

§ 371 Date: Nov. 2, 2010

(30) Foreign Application Priority Data
Mar. 13, 2009 (JP) 2009-061588

(51) Int. Cl. C23C 16/52; C23C 16/00

(52) U.S. Cl. 427/248.1; 118/724

(57) ABSTRACT

The object described above is achieved by providing a substrate processing apparatus comprising a chamber configured to process a substrate, a gas supply part configured to supply gas into the chamber, an exhaust part configured to exhaust the gas within the chamber, a first trap provided between the chamber and the exhaust part and connected to the chamber, and a second trap provided between the first trap and the exhaust part, characterized in that there is provided a temperature controller configured to set the first trap to a first temperature at which non-reaction components included in the gas react to form a polymer, and to set the second trap to a second temperature at which the non-reaction components included in the gas deposit as monomers.

### TECHNICAL FIELD

The present invention relates to substrate processing apparatuses, trap devices, control methods for substrate processing apparatuses, and control methods for trap devices.

### BACKGROUND ART

Polyimide is one example of an insulator material used in semiconductor devices. Because polyimide has a high adhesion and a low leak current, polyimide is used for interlayer insulation, passivation films, and the like.

A polyimide film may be formed by vapor deposition polymerization that uses PMDA (Pyromellitic Anhydride) and ODA (4,4′-Oxydianiline) as raw material monomers.

The vapor deposition polymerization vaporizes the PMDA and the ODA which are highly reactive monomers, and deposits the monomers on a substrate surface within a chamber. The polyimide film is obtained as a polymer by the polymerization and dehydration at the substrate surface.

In a substrate processing apparatus that carries out a deposition process employing the vapor deposition polymerization, the raw material monomers that do not contribute to the vapor deposition polymerization at the substrate surface may deposit within a vacuum pump that is used when exhausting gas inside of the chamber of the substrate processing apparatus. In order reduce undesirable effects of the raw material monomer depositing within the vacuum pump, a vacuum polymerization apparatus having a monomer trap provided with a water-cooled coil has been proposed (for example, Patent Document 1).

On the other hand, in a normal vacuum deposition apparatus that does not use the vaporized polymer material as the raw material, an eliminator is provided between the chamber and the vacuum pump in order to prevent non-reaction components within the gas being exhausted from mixing into the vacuum pump as foreign particles. One example of such an eliminator causes the non-reaction components to react within the elimination device and deposit on inner walls thereof (for example, Patent Document 2).

### PRIOR ART DOCUMENTS

Patent Document 1: Japanese Laid-Open Patent Publication No. 5-132759

Patent Document 2: Japanese Laid-Open Patent Publication No. 2000-070664

### DISCLOSURE OF THE INVENTION

### Problems to be Solved by the Invention

Accordingly, it is one object of the present invention to provide a substrate processing apparatus, a trap device, a control method for the substrate processing apparatus, and a control method for the trap device, which are suited for removing monomers having relatively low adhesion, such as PMDA and ODA.

### Means of Solving the Problems

The present invention provides a substrate processing apparatus comprising a chamber configured to process a substrate; a gas supply part configured to supply gas into the chamber; an exhaust part configured to exhaust the gas within the chamber; a first trap provided between the chamber and the exhaust part and connected to the chamber; and a second trap provided between the first trap and the exhaust part, characterized in that there is provided a temperature controller configured to set the first trap to a first temperature at which non-reaction components included in the gas react to form a polymer, and to set the second trap to a second temperature at which the non-reaction components included in the gas deposit as monomers.

The present invention may be characterized in that there is provided a connection valve provided between the first trap and the second trap, wherein the temperature controller sets the connection valve to a third temperature higher than the first temperature.

The present invention may be characterized in that the first temperature is set to 140° C. to 200° C., the second temperature is set to 120° C. or lower, and the third temperature is set to 200° C. or higher.

The present invention may be characterized in that the gas includes at least one of PMDA and ODA.

The present invention may be characterized in that the second trap has a mirror polished surface that makes contact with the gas.

The present invention may be characterized in that the second trap has a fluororesin coated surface that makes contact with the gas.

The present invention may be characterized in that the second trap has a glass coated surface that makes contact with the gas.

The present invention further provides a trap device provided between a chamber that has a gas supply part to supply gas thereto and is configured to process a substrate, and an exhaust part configured to exhaust the gas within the chamber, characterized in that there are provided a first trap connected to the chamber; a second trap provided between the first trap and the exhaust part; and a temperature controller configured to set the first trap to a first temperature at which non-reaction components included in the gas react to form a polymer, and to set the second trap to a second temperature at which the non-reaction components included in the gas deposit as monomers.

The present invention further provides a method for controlling a trap device provided between a chamber that has a gas supply part to supply gas thereto and is configured to process a substrate, and an exhaust part configured to exhaust the gas within the chamber, characterized in that the method for controlling a substrate processing apparatus comprises setting a first trap that is connected to the chamber to a first temperature at which non-reaction components included in the gas react to form a polymer; and setting a second trap that is provided between the first trap and the exhaust part to a second temperature at which the non-reaction components included in the gas deposit as monomers.

The present invention further provides a method for controlling a trap device provided between a chamber that has a gas supply part to supply gas thereto and is configured to process a substrate, and an exhaust part configured to exhaust the gas within the chamber, characterized in that the method for controlling the trap device comprises setting a first trap that is connected to the chamber to a first temperature at which non-reaction components included in the gas react to form a polymer; and setting a second trap that is provided between the first trap and the exhaust part to a second temperature at which the non-reaction components included in the gas deposit as monomers.

### EFFECTS OF THE INVENTION

According to one aspect of the present invention, the raw material monomers may be effectively removed in the trap device and the substrate processing apparatus using vaporized PMDA or ODA.

### BRIEF DESCRIPTION OF THE DRAWING

FIG. 1 is a diagram illustrating a structure of a deposition apparatus in one embodiment;

FIG. 2 is a diagram illustrating a structure of a trap device in one embodiment;

FIG. 3 is a perspective view illustrating a structure of a first trap;

FIG. 4 is a diagram for explaining a correlation of a surface area and a deposition rate within the first trap;

FIG. 5 is a diagram illustrating a structure of a second trap;

FIG. 6 is a perspective view illustrating the structure of the second trap;

FIG. 7 is a perspective view illustrating a structure of a cooling mechanism of the second trap;

FIG. 8 is a diagram illustrating a structure of a connection valve; and

FIG. 9 is a diagram for explaining a general system arrangement from a chamber up to a vacuum pump.

### BEST MODE OF CARRYING OUT THE INVENTION

A description will be given of embodiments of the present invention.

In one embodiment, a deposition apparatus obtains a polyimide film by vapor deposition polymerization, using PMDA and ODA as raw material monomers.

[Deposition Apparatus]

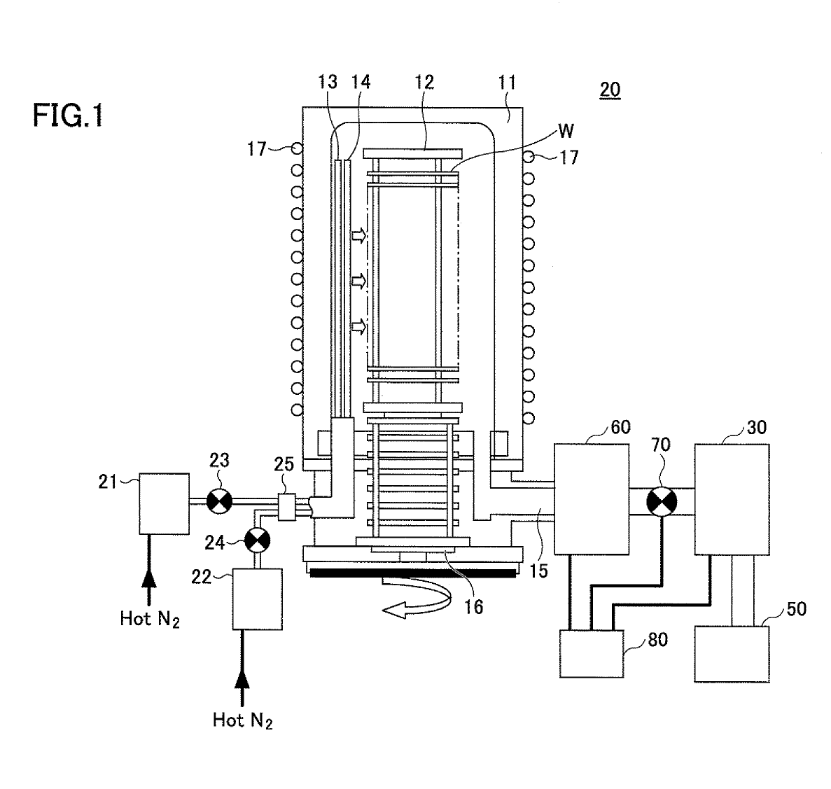

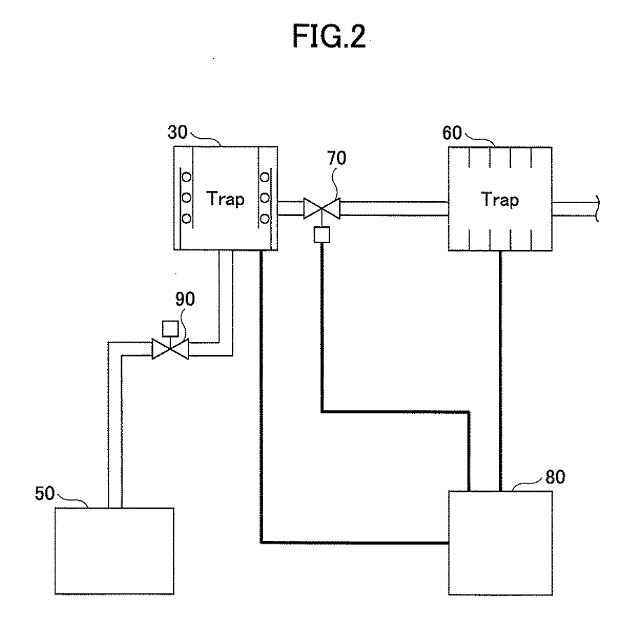

A description will be given of a trap device and a deposition apparatus in one embodiment, by referring to FIGS. 1 and 2. FIG. 1 is a diagram illustrating a structure of the deposition apparatus in one embodiment, and FIG. 2 is a diagram illustrating a structure of the trap device in one embodiment.

The deposition apparatus in this embodiment includes a wafer port 12 within a chamber 11 that may be exhausted by a vacuum pump 50, and a plurality of wafers W on which a polyimide film is to be deposited may be set in the wafer port 12. Injectors 13 and 14 for supplying vaporized PMDA and ODA are also provided within the chamber 11. Openings are provided on side surfaces of the injectors 13 and 14, and the vaporized PMDA and ODA from the injectors 13 and 14 are supplied in a horizontal direction with respect to the wafers W as indicated by arrows in FIG. 1. The vaporized PMDA and ODA that are supplied causes a vapor deposition polymerization reaction on the wafers W, and are deposited as polyimide films. The vaporized PMDA and ODA that do not contribute to the deposition of the polyimide film continue to flow as they are and are exhausted outside the chamber 11 via an exhaust port 15. In order to uniformly deposit the polyimide film on each wafer W, the wafer port 12 may be rotated by a rotating part 16. In addition, a heater 17 is provided outside the chamber 11 in order to heat the wafers W within the chamber 11 to a predetermined temperature.

The injector 13 connects to a PMDA evaporator 21 via an introduction part 25 and a valve 23, and the injector 14 connects to an ODA evaporator 22 via the introduction part 25 and the valve 24. Hence, the PMDA vaporized by the PMDA evaporator 21 and the ODA vaporized by the ODA evaporator 22 are supplied from the injectors 13 and 14.

High-temperature nitrogen gas is supplied to the PMDA evaporator 21 as carrier gas, and the PMDA evaporator 21 sublimates PMDA to supply the PMDA in the vapor form. For this reason, the PMDA evaporator 21 is maintained to a temperature of 260° C. High-temperature nitrogen gas is supplied to the ODA evaporator 22 as carrier gas, and the ODA evaporator 22 bubbles, by the hydrogen gas, the ODA that is in a liquid state by being heated to high temperature, in order to vaporize the ODA included in the nitrogen gas and to supply the ODA in the vapor form. For this reason, the ODA evaporator 22 is maintained to a temperature of 220° C. Thereafter, the vaporized PMDA and the vaporized ODA are supplied to the injectors 13 and 14 via the corresponding valves 23 and 24, and form the polyimide film on the surface of each wafer W set within the chamber 11. When depositing the polyimide film, the temperature within the chamber 11 is maintained to 200° C.

Accordingly, in the deposition apparatus of this embodiment, the vaporized PMDA and the vaporized ODA are jetted in the horizontal direction from the injectors 13 and 14, and deposits the polyimide film by the vapor deposition polymerization reaction.

The exhaust gas from the exhaust port 15 is exhausted from the vacuum pump 50 via a first trap 60 and a second trap 30. A connection valve 70 is provided between the first trap 60 and the second trap 30.

A temperature adjusting mechanism that is not illustrated, such as a heater, is provided on each of the first trap 60, the second trap 30, and the connection valve 70, and the temperature of each of the first trap 60, the second trap 30, and the connection valve 70 is controlled to a predetermined temperature by a controller 80.

In one embodiment, the trap device includes the first trap 60 and the second trap 30, and the connection valve 70 may be provided between the first trap 60 and the second trap 30. In addition, as illustrated in FIG. 2, a valve 90 may be provided between the second trap 30 and the vacuum pump 50.

[First Trap]

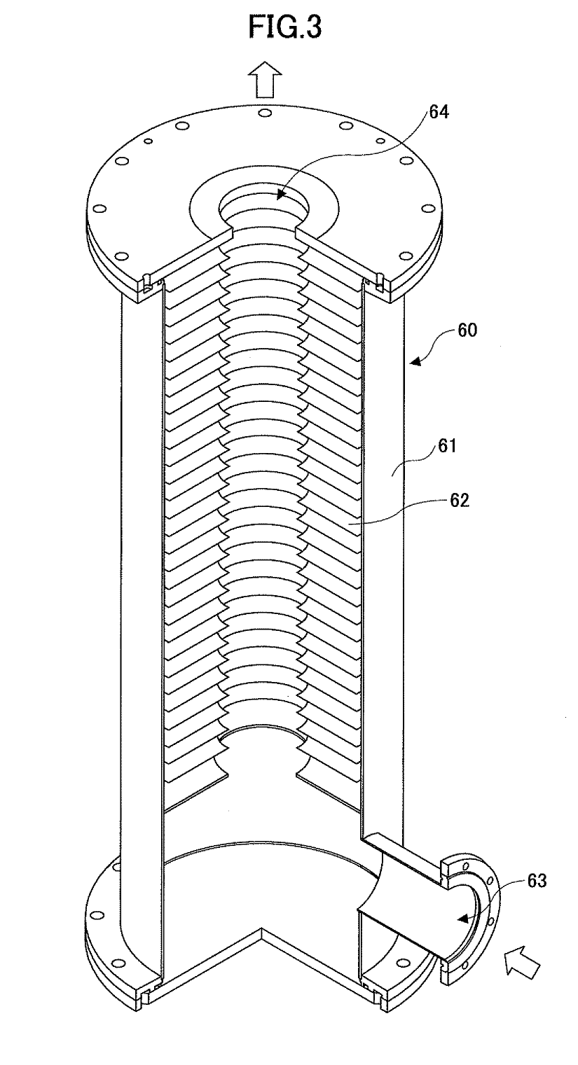

Next, a description will be given of the first trap 60. FIG. 3 is a perspective view illustrating a structure of the first trap 60. The first trap 60 has a structure in which a plurality of disk-shaped fins 62 are arranged inside a hollow cylindrical casing 61. An inlet part 63 of the first trap 60 connects to the exhaust port 15 of the chamber 11, and exhausts the gas from the vacuum pump 50 via the second trap 30 and the like, in order to supply the gas that is to be exhausted from the inlet part 63 to the inside of the first trap 60. The first trap 60 is maintained to 140° C. to 200° C. by the controller 80, and thus, the plurality of fins 62 inside the first trap 60 are also maintained to the same temperature. Because the vaporized PMDA and ODA react and form the polyimide at these temperatures, the PMDA and the ODA flowing into the first trap 60 from the chamber 11 react and form a polyimide film on surfaces of the fins 62. Hence, the PMDA and the ODA existing in vapor form within the exhaust gas are caused to react with each other, in order to remove as much PMDA and ODA as possible from the exhaust gas, and are thereafter exhausted from an exhaust port 64.

The first trap 60 in this embodiment has the fins 62 provided in a plurality of stages to become approximately perpendicular to an exhaust gas passage within the casing 61. In other words, the exhaust gas passage is formed by openings in the fins 62 that are arranged in the plurality of stages. By arranging the fins 62 in the plurality of stages, it becomes possible to cause the PMDA and the ODA within the exhaust gas to efficiently react and deposit the polyimide film on the fins 62, and to efficiently remove the PMDA and the ODA existing in the vapor form within the exhaust gas.

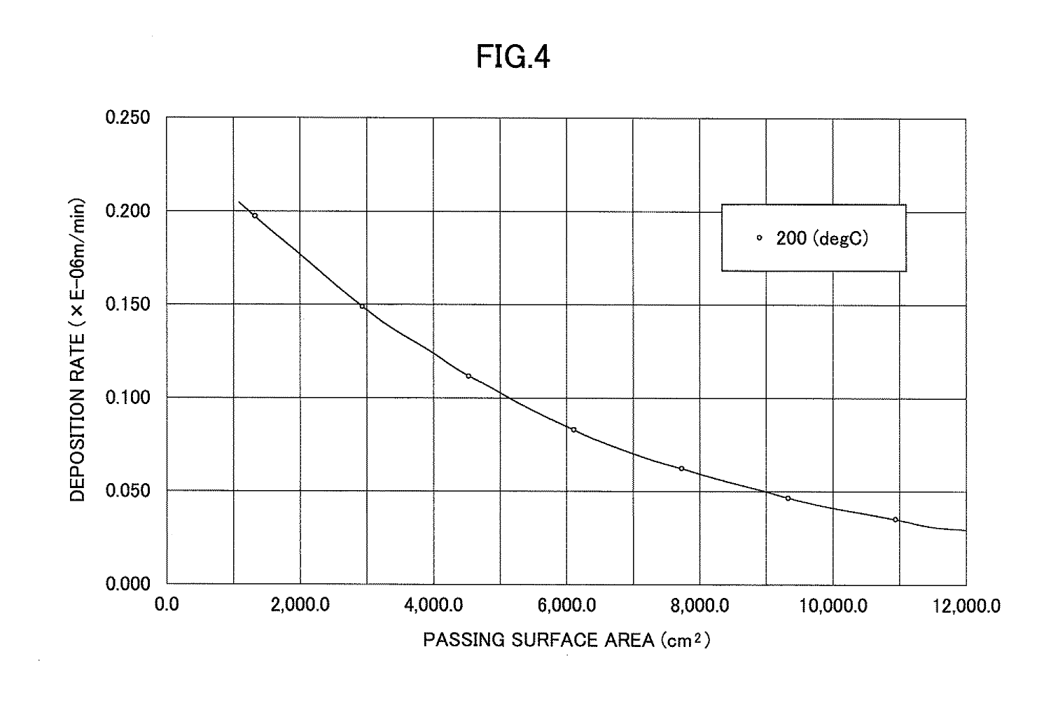

FIG. 4 is a diagram for explaining a correlation of a surface area of the exhaust gas passage, that is, the surface area through which the exhaust gas passes within the first trap 60, and a deposition rate achieved by the gas within the exhaust gas that passed through the exhaust gas passage within the first trap 60. As the surface area of the exhaust gas passage increases, the deposition rate achieved by the gas within the exhaust gas that passed through the exhaust gas passage decreases. Accordingly, the PMDA and the ODA within the exhaust gas are removed more as the surface area of the exhaust gas passage increases.

For example, in the first trap 60 of this embodiment, the casing 61 has a height of 1000 mm and an inner diameter of 310 mm, the fins 62 have an outer diameter of 300 mm and an inner diameter of 110 mm, and the fins 62 are arranged at a pitch of 24 mm and are provided in 30 stages.

[Second Trap]

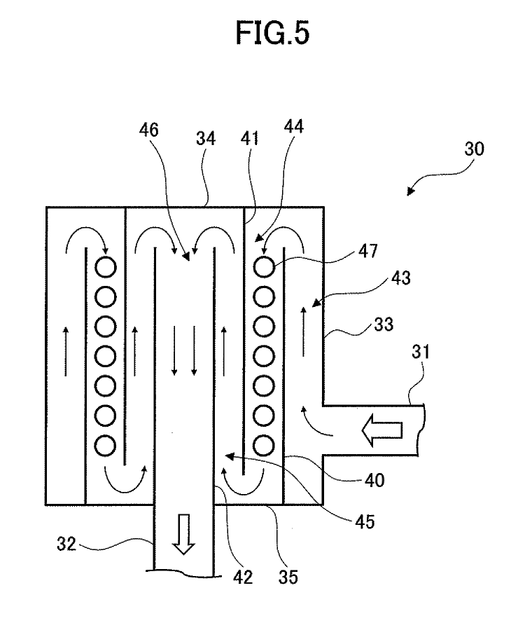

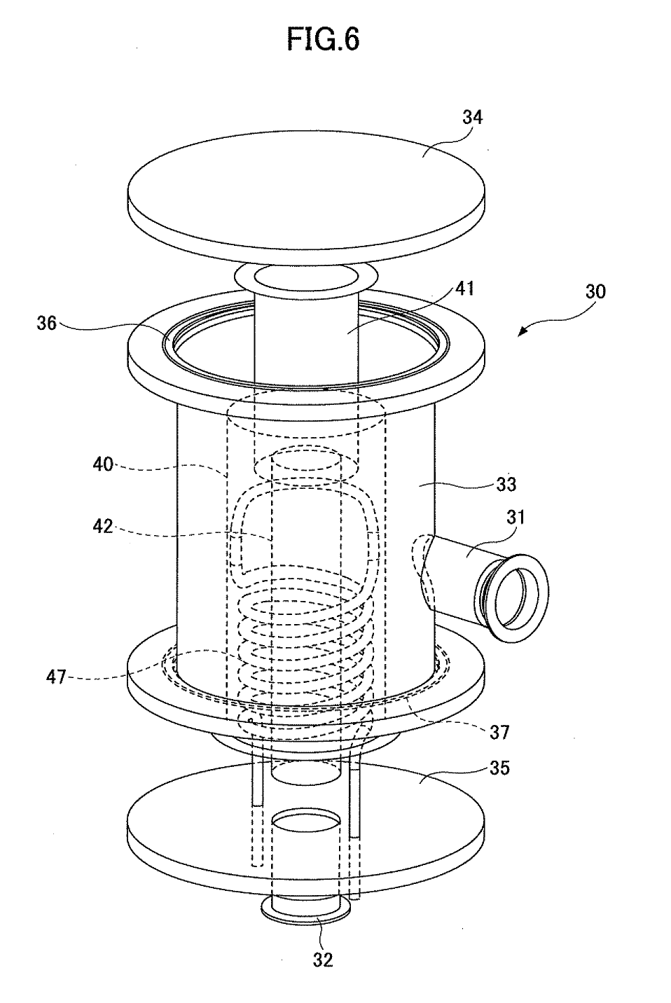

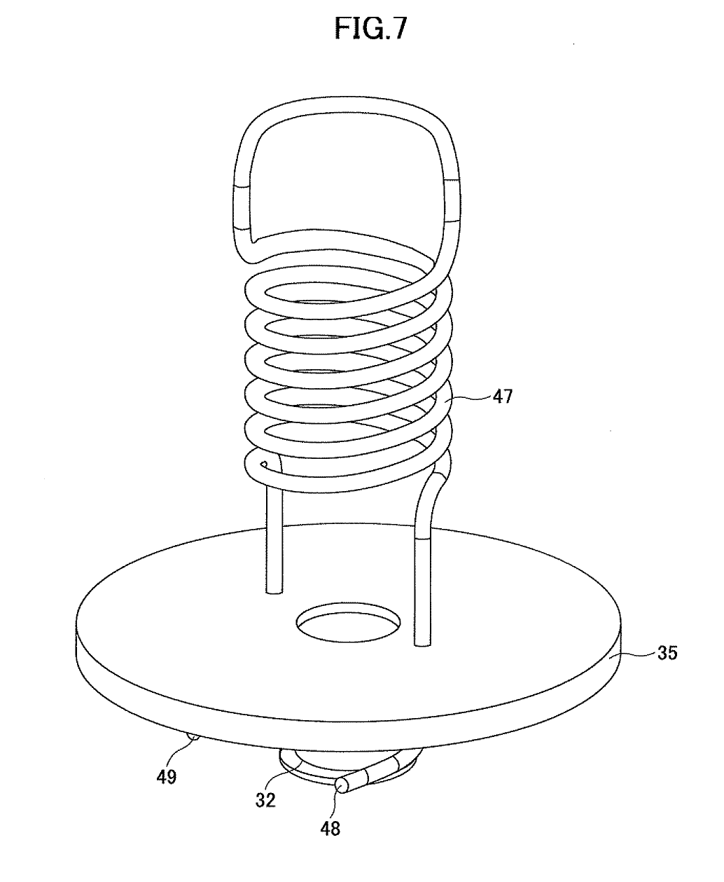

Next, a description will be given of the second trap 30 of this embodiment, by referring to FIGS. 5, 6 and 7. Outer walls of the second trap 30 in this embodiment are formed by a side surface part 33, a top surface part 34, and a bottom surface part 35. The side surface part 33 and the top surface part 34 are connected via an O-ring that is not illustrated and is provided in a groove 36 of the side surface part 33. In addition, the side surface part 33 and the bottom surface part 35 are connected via an O-ring that is not illustrated and is provided in a groove 37 of the side surface part 33. The second trap 30 includes an inlet port 31 provided in the side surface part 33, and an outlet port 32 provided in the bottom surface part 35. The inlet port 31 of the second trap 30 connects to the exhaust port 64 of the first trap 60 via the connection valve 70, and the PMDA and the ODA in the vapor form and exhausted from the exhaust port 64 of the first trap 60 flow into the second trap 30 via the exhaust port 15 and the inlet port 31. Further, the outlet port 32 of the second trap 30 connects to the vacuum pump 50, and a gas flow is generated within the second trap 30 due to the exhaust caused by the vacuum pump 50.

Bulkheads 40, 41, and 42 are provided within the second trap 30. The bulkhead 40 connects to the bottom surface part 35 forming the outer wall of the second trap 30, the bulkhead 41 connects to the top surface part 34 forming the outer wall of the second trap 30, and the bulkhead 42 connects to the bottom surface part 35 forming the outer wall of the second trap 30. Hence, a first passage 43 is formed by the side surface part 33 forming the outer wall of the second trap 30 and the bulkhead 40 on the inside, a second passage 44 is formed by the bulkhead 40 and the bulkhead 41, a third passage 45 is formed by the bulkhead 41 and the bulkhead 42, and a fourth passage 46 is formed inside the bulkhead 42. The first passage 43, the second passage 44, the third passage 45, and the fourth passage 46 are formed concentrically, in an order, in a direction towards a center of the second trap 30. Hence, the inlet port 31 that connects to the passage 43 is formed towards the passage 43 along a tangential direction of the side surface part 33 having the cylindrical tube shape, so that the gas may easily flow to the passage 43 without resistance at the side surface part 33 forming the outer wall of the second trap 40. In addition, the outlet port 32 that connects to the passage 46 is provided in a central part of the bottom surface part forming the outer wall of the second trap 30.

Water-cooled pipe 47, that forms a cooling mechanism, is provided in the second passage, 44, and this water-cooled pipe 47 has a function of lowering the temperature of the gas flowing thereto.

The gas, including the PMDA and the ODA in the vapor form, entering the second trap 30 from the inlet port 31, flows in an upward direction in FIGS. 5 through 7 in the passage 43 that is formed by the bulkhead 40 and the inner side of the side surface part 33 forming the outer wall of the second trap 30. This is because the bulkhead 40 connects to the bottom surface part 35 forming the outer wall of the second trap 30, a gap is formed between the bulkhead 40 and the inner side of the top surface part 34 forming the outer wall of the second trap 30, and the gas entering the second trap 30 flows towards this gap.

Thereafter, the gas flows in a downward direction in FIGS. 5 through 7 in the passage 44 formed by the bulkheads 40 and 41. This is because the bulkhead 41 connects to the top surface part 34 forming the outer wall of the second trap 30, a gap is formed between the bulkhead 40 and the inner side of the bottom surface part 35 forming the outer wall of the second trap 30, and the gas entering the second trap 30 flows towards this gap. In addition, the water-cooled pipe 47 is provided in the passage 44, and the PMDA and the ODA in the vapor form entering the passage 44 are cooled and coagulate on the surface of the water-cooled pipe 47 or the like. In this embodiment, the water-cooled pipe 47 has a large surface area for cooling so that the gas may be cooled rapidly. In addition, the PMDA and the ODA in the coagulated and solidified form do not easily adhere on the surface of water-cooled pipe 47 because the water-cooled pipe 47 has the cylindrical tube shape. Hence, the PMDA and the ODA in the coagulated and solidified form on the surface of the water-cooled pipe 47 or the like may separate from the surface of the water-cooled pipe 47 and fall with the downward flow along the passage 44 to deposit on the bottom surface part 35 forming the outer wall of the second trap 30, that is, on the inner side of the bottom surface part 35 between the bulkheads 40 and 42.

Then, the gas flows in the upward direction in FIGS. 5 through 7 in the passage 45 formed by the bulkheads 41 and 42. This is because the bulkhead 42 connects to the bottom surface part 35 forming the outer wall of the second trap 30, a gap is formed between the bulkhead 42 and the inner side of the top surface part 34 forming the outer wall of the second trap 30, and the gas entering the second trap 30 flows towards this gap.

Thereafter, the gas flows in the downward direction in FIGS. 5 through 7 in the passage 46 formed on the inner side of the bulkhead 42. The passage 46 connects to the vacuum pump 50 via the outlet port 32, and the gas flow towards the outlet port 32. In this embodiment, the second trap 30 is set up so that the downward direction thereof matches the direction in which the gravity acts, and the upward direction of the second trap 30 is opposite to the downward direction, that is, rotated by approximately 180° relative to the downward direction. The directions or orientations of the second trap 30 may be slightly different as long as effects similar to those obtainable in this embodiment are obtainable by the slightly different directions or orientations.

In the second trap 30 of this embodiment, the water-cooled pipe 47 is arranged in the passage 44, that is, in the passage in which the gas flows downwards. This arrangement is employed in order to facilitate the coagulated PMDA and ODA on the surface of the water-cooled pipe 47 or the like to fall by the downward flow of the gas and to deposit on the inner side of the bottom surface part 35 forming the outer wall of the second trap 30. The coagulated PMDA and ODA deposit on the inner side of the bottom surface part 35 by the effects of gravity described above. In addition, in the passage 44, the downward flow of the gas promotes the separation of the coagulated PMDA and ODA on the surface of the water-cooled pipe 47, and also promotes deposition of the coagulated PMDA and ODA on the inner side of the bottom surface part 35. Because the coagulated PMDA and ODA adhered on the surface of the water-cooled pipe 47 will not deposit on the surface of the water-cooled pipe 47, the cooling state may always be maintained constant.

The velocity of the gas flowing inside the second trap 30 may be adjusted by the exhaust rate of the vacuum pump 50, so that the coagulated PMDA and ODA deposited on the inner side of the bottom surface part 35 will not be scattered by the upward flow in the passage 45. In addition, the bulkheads 40, 41 and 42 within the second trap 30 may be arranged by taking into consideration the velocity of the gas. For example, it is undesirable for the interval between the bulkhead 41 and the bottom surface part 35 to be narrow, because the narrow interval may cause the gas flow to more easily scatter the PMDA and the ODA deposited on the inner side of the bottom surface part 35.

A foreign particle remover that is not illustrated is provided on the bottom surface part 35 forming the outer wall of the second trap 30, in a region between the bulkhead 40 and the bulkhead 42. Maintenance and the like may easily be performed by removing the PMDA and the ODA that are deposited on the bottom surface part 35 by the foreign particle remover.

Water that is controlled of its temperature and flow rate is supplied from a supply port 48 to the water-cooled pipe 47 and drained via a drain port 49. The surface of the water-cooled pipe 47 is subjected to mirror polishing in order to prevent the PMDA and the ODA coagulated on the surface of the water-cooled pipe 47 from adhering onto the surface of the water-cooled pipe 47. The mirror polishing may be achieved by electrolytic polishing, chemical polishing, chemical mechanical polishing, mechanical polishing, and the like.

A coating for minimizing the PMDA and ODA adhesion may be formed on the surface of the water-cooled pipe 47. For example, fluororesin, glass, or the like may be coated on the surface of the water-cooled pipe 47. Further, a material for minimizing the PMDA and ODA adhesion may be plated on the surface of the water-cooled pipe 47.

A vibrator mechanism that is not illustrated may be provided to vibrate the water-cooled pipe 47, in order to promote the separation of the coagulated PMDA and ODA from the surface of the water-cooled pipe 47 by vibration.

The embodiment described above uses the water-cooled pipe 47 as the cooling mechanism, however, the cooling mechanism may have any structure that provides a large cooling surface area to facilitate the separation of the coagulated PMDA and ODA. For this reason, the cooling mechanism preferably has a convex surface, as in the case of the water-cooled pipe 47, rather than a concave surface of a planar surface.

In this embodiment, the second trap 30 is provided to coagulate and remove the PMDA and the ODA existing within the exhaust gas. Hence, the entire second trap 30 is controlled to a temperature of 120° C. or lower by the controller 80.

The temperature, the flow rate, and the like of the water flowing in the water-cooled pipe 47 of the second trap 30 in this embodiment may also be controlled by a control program that runs on a computer that is not illustrated. This control program may be stored in a computer-readable storage medium.

[Valve]

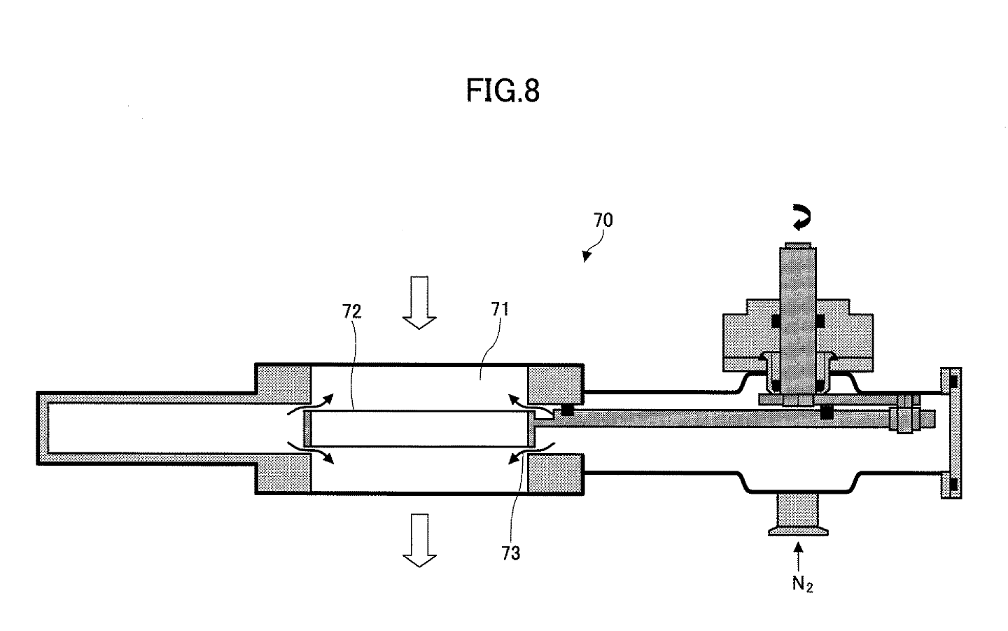

Next, a description will be given of the connection valve 70 that is provided between the first trap 60 and the second trap 30. As illustrated in FIG. 8, the connection valve 70 opens and closes the passage between the first trap 60 and the second trap 30. The connection valve 70 includes an opening and closing part 72 within an opening 71, and the passage is opened or closed via the opening 71 depending on a movement of the opening and closing part 72. In addition, a gas purge 73 may be performed depending on a movement of the opening and closing part 72.

Preferably, the connection valve 70 is set to a temperature that is 200° C. or higher and as high as possible, in order to prevent the PMDA and ODA existing within the exhaust gas from reacting with each other to generate the polyimide and to prevent the polyimide from adhering thereon. By taking into consideration the heat resistance and the like of the connection valve 70, the connection valve 70 may be set to a temperature of 200° C. to 260° C. If the heat resistance of the connection valve 70 tolerates, the adhesion of the polyimide may be prevented by setting the temperature of the connection valve 70 to 450° C. or higher because the polyimide decomposes at such high temperatures. In addition, the opening 71 of the connection valve 70 preferably has a wide shape in order not to deteriorate the conductance.

[Temperature Setting]

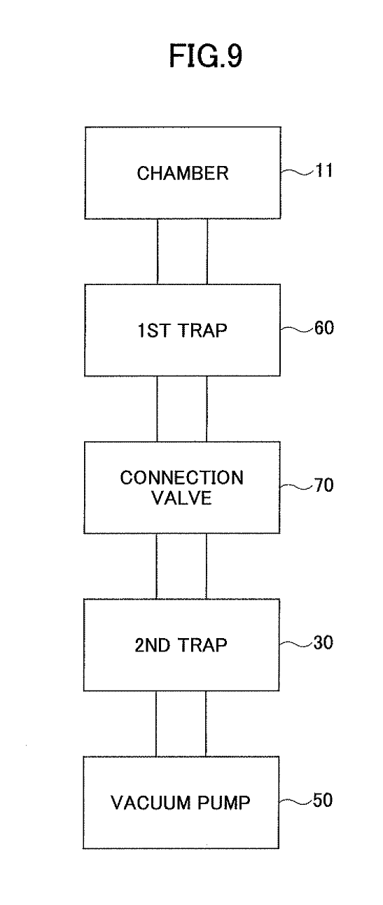

Next, a description will be given of the temperature relationship of the first trap 60, the second trap 30, the connection valve 70, and the chamber 11. FIG. 9 is a diagram for explaining an exhaust passage from the chamber 11 up to the vacuum pump 50. More particularly, the chamber 11, the first trap 60, the connection valve 70, the second trap 30, and the vacuum pump 50 connect in this order. In this embodiment, the temperature of the chamber 11 is set to approximately 200° C., the first trap 60 is set to a temperature of 140° C. to 200° C., the second trap 30 is set to a temperature of 120° C. or lower, and the connection valve 70 is set to a temperature of 200° C. to 260° C., as described above. Such temperature settings of the trap device may be controlled by the controller 80.

The first trap 60 is set to a temperature lower than the temperature of the chamber 11. In addition, the connection valve 70 is set to a temperature higher than the temperatures of the chamber 11 and the first trap 60. Further, the second trap 30 is set to a temperature that is lower than the temperature of the first trap 60, and at which the PMDA and the ODA coagulate.

By the temperature settings described above, the polyimide generated by the reaction between the PMDA and the ODA is removed in the first trap 60, the adhesion of the polyimide is prevented as much as possible in the connection valve 70. In this state, the exhaust gas is supplied to the second trap 30, and the PMDA and the ODA are coagulated and removed in the second trap 30.

Therefore, according to this embodiment, the polyimide adheres on the fins 62 in the first trap 60 and is removed. The PMDA and the ODA coagulate on the mirror polished surface in the second trap 30, and falls without adhering on the mirror polished surface. As a result, the PMDA and the ODA within the exhaust gas are removed without adversely affecting the conductance. In addition, the maintenance cost and the like may be minimized because each of the first trap 60 and the second trap 30 may be replaced independently. Particularly since a large portion of the PMDA and ODA within the exhaust gas is removed in the first trap 60, the frequency of replacing the second trap 30 may be extremely low.

In the deposition apparatus of this embodiment, the vacuum pump 50 may be formed by a dry pump, a rotary vane pump, a scroll pump, or the like. A booster pump, a screw pump, or the like may be used for the dry pump. Such vacuum pumps have a large displacement and are suited for film deposition while supplying the gas. However, such vacuum pumps may easily fail particularly when deposits of the polyimide occur within the vacuum pumps. Hence, even when such vacuum pumps are used as the vacuum pump 50 described above, the vacuum pump 50 may be prevented from failing by connecting the trap device of this embodiment between the chamber 11 and the vacuum pump 50. Similarly, the vacuum pump may also be prevented from failing in the deposition apparatus having a structure that includes a trap device with such an arrangement.

Further, the present invention is not limited to these embodiments, but various variations and modifications may be made without departing from the scope of the present invention.

This application claims the benefit of a Japanese Patent Application No. 2009-061588 filed on Mar. 13, 2009, in the Japanese Patent Office, the entire disclosure of which is hereby incorporated by reference.

### INDUSTRIAL APPLICABILITY

The present invention is applicable to substrate processing apparatuses configured to stack materials on a substrate such as a wafer.

### DESCRIPTION OF THE REFERENCE NUMERALS

11 Chamber
12 Wafer Board
13 Injector
14 Injector
15 Exhaust Port
16 Rotating part
17 Heater
21 PMDA Evaporator
22 ODA Evaporator
23 Valve
24 Valve
25 Induction Part
30 Second Trap
31 Inlet Port
32 Outlet Port
33 Side Surface Part
34 Top Surface Part
35 Bottom Surface Part
36, 37 Groove
40, 41, 42 Bulkhead
43, 44, 45, 46 Passage
47 Water-Cooling Pipe
48 Supply Port
49 Drain Port
50 Vacuum Pump
60 First Trap
70 Connection Valve
80 Controller
W Wafer

1. A substrate processing apparatus comprising:
a chamber configured to process a substrate;
a gas supply part configured to supply gas into the chamber;
an exhaust part configured to exhaust the gas within the chamber;
a first trap provided between the chamber and the exhaust part and connected to the chamber;
a second trap provided between the first trap and the exhaust part; and
a temperature controller configured to set the first trap to a first temperature at which non-reaction components included in the gas react to form a polymer, and to set the second trap to a second temperature at which the non-reaction components included in the gas deposit as monomers.

2. The substrate processing apparatus as claimed in claim 1, further comprising:
a connection valve provided between the first trap and the second trap,
wherein the temperature controller sets the connection valve to a third temperature higher than the first temperature.

3. The substrate processing apparatus as claimed in claim 2, wherein the first temperature is set to 140° C. to 200° C., the second temperature is set to 120° C. or lower, and the third temperature is set to 200° C. or higher.

4. The substrate processing apparatus as claimed in claim 1, wherein the gas includes at least one of PMDA and ODA.

5. The substrate processing apparatus as claimed in claim 1, wherein the second trap has a mirror polished surface that makes contact with the gas.

6. The substrate processing apparatus as claimed in claim 1, wherein the second trap has a fluororesin coated surface that makes contact with the gas.

7. The substrate processing apparatus as claimed in claim 1, wherein the second trap has a glass coated surface that makes contact with the gas.

8. A trap device provided between a chamber that has a gas supply part to supply gas thereto and is configured to process a substrate, and an exhaust part configured to exhaust the gas within the chamber, said trap device comprising:
a first trap connected to the chamber;
a second trap provided between the first trap and the exhaust part; and
a temperature controller configured to set the first trap to a first temperature at which non-reaction components included in the gas react to form a polymer, and to set the second trap to a second temperature at which the non-reaction components included in the gas deposit as monomers.

9. The trap device as claimed in claim 8, further comprising:
a connection valve provided between the first trap and the second trap,
wherein the temperature controller sets the connection valve to a third temperature higher than the first temperature.

10. The trap device as claimed in claim 9, wherein the first temperature is set to 140° C. to 200° C., the second temperature is set to 120° C. or lower, and the third temperature is set to 200° C. or higher.

11. The trap device as claimed in claim 8, wherein the gas includes at least one of PMDA and ODA.

12. The trap device as claimed in claim 8, wherein the second trap has a mirror polished surface that makes contact with the gas.

13. The trap device as claimed in claim 8, wherein the second trap has a fluororesin coated surface that makes contact with the gas.

14. The trap device as claimed in claim 8, wherein the second trap has a glass coated surface that makes contact with the gas.

15. A method for controlling a substrate processing apparatus having a trap device provided between a chamber that has a gas supply part to supply gas thereto and is configured to process a substrate, and an exhaust part configured to exhaust the gas within the chamber, the method comprising:
setting a first trap that is connected to the chamber to a first temperature at which non-reaction components included in the gas react to form a polymer; and
setting a second trap that is provided between the first trap and the exhaust part to a second temperature at which the non-reaction components included in the gas deposit as monomers.

16. The method for controlling the substrate processing apparatus as claimed in claim 15, wherein:
a connection valve is provided between the first trap and the second trap, and
the connection valve is set to a third temperature higher than the first temperature.

17. (canceled)

18. (canceled)
